(19) United States
(12) Patent Application Publication
(10) Pub. No.: US 2019/0140668 A1
(43) Pub. Date: May 9, 2019

(54) SEMICONDUCTOR MEMORY DEVICE AND MEMORY SYSTEM INCLUDING THE SAME FOR ADAPTIVE ERROR CHECK AND CORRECTION

(71) Applicant: SAMSUNG ELECTRONICS CO., LTD., Suwon-si (KR)

(72) Inventors: DUK-SUNG KIM, Hwaseong-si (KR); Kwang-Hyun Kim, Seongnam-si (KR)

(21) Appl. No.: 16/104,497

(22) Filed: Aug. 17, 2018

(30) Foreign Application Priority Data
Nov. 9, 2017 (KR) 10-2017-0148431

(51) Int. Cl. H03M 13/35; G06F 11/10; G11C 29/52

(52) U.S. Cl. CPC H03M 13/35; G11C 29/52; G06F 11/1068

(57) ABSTRACT

A semiconductor memory device includes a memory cell array and an error check and correction (ECC) circuit. The ECC circuit performs ECC encoding of write data that are stored in the memory cell array and performs ECC decoding of read data corresponding to the write data that are read out from the memory cell array, based on an on-die ECC level corresponding to the write data. The on-die ECC level is determined among a plurality of on-die ECC levels depending on an importance degree of the write data.

### CROSS-REFERENCE TO RELATED APPLICATION

This U.S. non-provisional application claims priority under 35 U.S.C. § 119 to Korean Patent Application No. 10-2017-0148431, filed on Nov. 9, 2017 in the Korean Intellectual Property Office (KIPO), the disclosure of which is incorporated by reference herein in its entirety.

### TECHNICAL FIELD

Exemplary embodiments of the inventive concept relate generally to semiconductor integrated circuits, and more particularly, to a semiconductor memory device and a memory system including the semiconductor memory device for adaptive error check and correction.

### DISCUSSION OF RELATED ART

Semiconductor memory devices may be classified into non-volatile memory devices such as flash memory devices and volatile memory devices such as dynamic random access memory (DRAMs). The high speed operation and cost efficiency of DRAMs provides for their effective use as system memories. Due to the continuing shrinkage in fabrication design rules for DRAMs, bit errors in the DRAM memory cells may rapidly increase and yield of DRAMs may be lowered.

### SUMMARY

According to exemplary embodiments of the inventive concept, a semiconductor memory device includes a memory cell array and an error check and correction (ECC) circuit. The ECC circuit performs ECC encoding of write data that are stored in the memory cell array and performs ECC decoding of read data corresponding to the write data that are read out from the memory cell array, based on an on-die ECC level corresponding to the write data. The on-die ECC level is determined among a plurality of on-die ECC levels depending on an importance degree of the write data.

According to exemplary embodiments of the inventive concept, a memory system includes at least one semiconductor memory device and a memory controller configured to control the at least one semiconductor memory device. The memory controller determines an on-die ECC level corresponding to write data among a plurality of on-die ECC levels depending on an importance degree of the write data that are stored in a memory cell array of the at least one semiconductor memory device. The at least one semiconductor memory device performs ECC encoding of the write data and ECC decoding of read data corresponding to the write data based on the on-die ECC level corresponding to the write data.

According to exemplary embodiments of the inventive concept, a method of controlling an error check and correction (ECC) of a semiconductor memory device includes determining, by a memory controller, an on-die ECC level corresponding to write data among a plurality of on-die ECC levels depending on an importance degree of the write data that are stored in a memory cell array of the semiconductor memory device, and performing, by the semiconductor memory device, ECC encoding of the write data and ECC decoding of read data corresponding to the write data based on the on-die ECC level corresponding to the write data.

### BRIEF DESCRIPTION OF THE DRAWINGS

The above and other features of the inventive concept will be more clearly understood by describing in detail exemplary embodiments thereof with reference to the accompanying drawings.

FIG. 1 is a flowchart illustrating a method of controlling an on-die error check and correction (ECC) according to an exemplary embodiment of the inventive concept.

FIG. 2 is a block diagram illustrating a memory system according to an exemplary embodiment of the inventive concept.

FIG. 3 is a diagram for describing on-die ECC levels according to data bits and parity bits according to an exemplary embodiment of the inventive concept.

FIG. 4 is a diagram illustrating an example of setting on-die ECC levels according to an exemplary embodiment of the inventive concept.

FIG. 5 is a block diagram illustrating a semiconductor memory device according to an exemplary embodiment of the inventive concept.

FIG. 6 illustrates a portion of the semiconductor memory device of FIG. 5 according to an exemplary embodiment of the inventive concept.

FIGS. 7 and 8 are diagrams illustrating a fixed configuration of a memory cell array for implementing a plurality of on-die ECC levels according to exemplary embodiments of the inventive concept.

FIG. 9 is a diagram illustrating a variable configuration of a memory cell array for implementing a plurality of on-die ECC levels according to an exemplary embodiment of the inventive concept.

FIG. 10 illustrates a portion of the semiconductor memory device of FIG. 5 according to an exemplary embodiment of the inventive concept.

FIGS. 11 and 12 are diagrams illustrating a fixed configuration of a memory cell array for implementing a plurality of on-die ECC levels according to exemplary embodiments of the inventive concept.

FIG. 13 is a diagram illustrating a variable configuration of a memory cell array for implementing a plurality of on-die ECC levels according to an exemplary embodiment of the inventive concept.

FIG. 14 is a diagram illustrating an ECC circuit included in the semiconductor memory device of FIG. 5 according to an exemplary embodiment of the inventive concept.

FIG. 15 is a block diagram illustrating an ECC engine included in the ECC circuit of FIG. 14 according to an exemplary embodiment of the inventive concept.

FIG. 16 is a diagram illustrating a parity generator included in the ECC engine of FIG. 15 according to an exemplary embodiment of the inventive concept.

FIG. 17 is a diagram illustrating a data corrector included in the ECC circuit of FIG. 14 according to an exemplary embodiment of the inventive concept.

FIGS. 18 and 19 are flowcharts illustrating a method of controlling on-die ECC according to exemplary embodiments of the inventive concept.

FIGS. 20A and 20B are diagrams illustrating a stacked memory device according to exemplary embodiments of the inventive concept.

FIG. 21 is a block diagram illustrating a mobile system according to an exemplary embodiment of the inventive concept.

### DETAILED DESCRIPTION OF THE EMBODIMENTS

Exemplary embodiments of the inventive concept provide semiconductor memory devices, systems including the semiconductor memory devices, and associated methods capable of performing an on-die error check and correction (ECC) adaptively.

Exemplary embodiments of the inventive concept will be described more fully hereinafter with reference to the accompanying drawings. Like reference numerals may refer to like elements throughout this application.

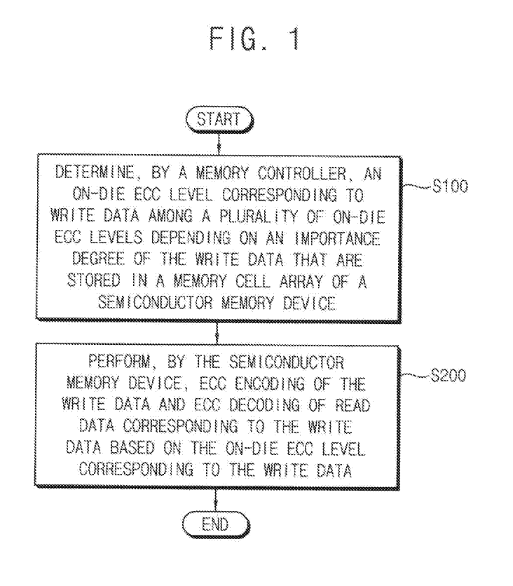

FIG. 1 is a flowchart illustrating a method of controlling an on-die error check and correction (ECC) according to an exemplary embodiment of the inventive concept.

Referring to FIG. 1, by a memory controller, an on-die ECC level corresponding to write data is determined among a plurality of on-die ECC levels depending on an importance degree of write data that are stored in a memory cell array of a semiconductor memory device (S100). The importance degree of the write data may be determined according to a type of the write data. For example, a relatively high on-die ECC level may be assigned to important data such as an operating system (OS) because a fatal effect on a system may result if an error in the operating system is uncorrectable. In contrast, a relatively low on-die ECC level may be assigned to simple data such as image data.

As such, the on-die ECC level corresponding to the write data may be determined to be higher when the importance degree of the write data is higher. As will be described below, a ratio of a bit number of parity data corresponding to the write data to a bit number of the write data may be set to be higher as the on-die ECC level corresponding to the write data increases. As a result, a probability of error correction may be increased by increasing the ratio of the bit number of the parity data to the bit number of the write data, as the importance degree of the write data is increased.

By the semiconductor memory device, ECC encoding of the write data and ECC decoding of read data corresponding to the write data may be performed based on the on-die ECC level corresponding to the write data (S200). The on-die ECC is differentiated from a system level ECC that is performed by the memory controller or a host device. The on-die ECC represents an ECC that is performed autonomously in the semiconductor memory device. The parity data of the on-die ECC are generated in the semiconductor memory device and the parity data are not provided to an external device.

To apply different on-die ECC levels depending on the importance degree of the write data, at least two memory regions among a plurality of memory regions included in the memory cell array may be configured such that a ratio of sizes of the data region and the parity region may be different with respect to the at least two memory regions. Each memory region may include the data region storing the write data and the parity region storing the parity data. In exemplary embodiments of the inventive concept, the memory regions may have fixed configurations for applying the plurality of on-die ECC levels. In exemplary embodiments of the inventive concept, the memory regions may have variable configurations for applying the plurality of on-die ECC levels.

As such, the method of controlling an on-die ECC may reduce a size of the semiconductor memory device and enhance efficiency of the on-die ECC by applying different on-die ECC levels depending on the importance degree of the write data.

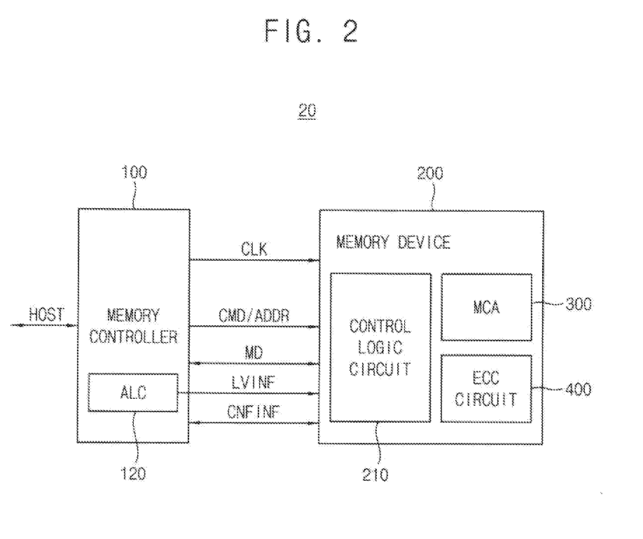

FIG. 2 is a block diagram illustrating a memory system according to an exemplary embodiment of the inventive concept.

Referring to FIG. 2, a memory system 20 includes a memory controller 100 and a semiconductor memory device 200.

The memory controller 100 may control an overall operation of the memory system 20, and the memory controller 100 may control an overall data exchange between an external host device and the semiconductor memory device 200. For example, the memory controller 100 may write data in the semiconductor memory device 200 or read data from the semiconductor memory device 200 in response to a request from the host device. In addition, the memory controller 100 may issue operation commands to the semiconductor memory device 200 for controlling the semiconductor memory device 200.

In exemplary embodiments of the inventive concept, the semiconductor memory device 200 may be a volatile memory such as a dynamic random access memory (DRAM), a synchronous DRAM (SRAM), a low power double data rate (LPDDR) SRAM, etc. In exemplary embodiments of the inventive concept, the semiconductor memory device 200 may be a non-volatile memory such as a phase change random access memory (PRAM), a resistive random access memory (RRAM), a magnetic random access memory (MRAM), a ferroelectric random access memory (FRAM), etc. The semiconductor memory device 200 is not limited to a particular type of memory and may be any type of memory having an on-die ECC.

The memory controller 100 transmits a clock signal CLK, a command CMD, and an address (signal) ADDR to the semiconductor memory device 200 and exchanges data MD with the semiconductor memory device 200.

The semiconductor memory device 200 includes a memory cell array 300 that stores the data MD, an error correction code or error check and correction (ECC) circuit 400, and a control logic circuit 210. The ECC circuit 400 may include a plurality of ECC engines corresponding to a plurality of bank arrays included in the memory cell array 300.

The memory system 20 may communicate with an external host device through interface protocols such as Peripheral Component Interconnect-Express (PCI-E), Advanced Technology Attachment (ATA), Serial ATA (SATA), Parallel ATA (PATA), Serial Attached SCSI (SAS), etc. When the external host device transmits a request for a write operation to the memory controller 100, the external host device may also determine and transmit an importance degree of write data to the memory controller 100.

The memory controller 100 may include an ECC allocator ALC 120 configured to determine an on-die ECC level corresponding to the write data based on the importance degree of the write data. The importance degree of the write data may be provided from the external host device or may be determined by a memory management scenario of the memory controller 100. The on-die ECC level corresponding to the write data may be provided as ECC level information LVINF to the semiconductor memory device 200. The semiconductor memory device 200 may perform the on-die ECC corresponding to the on-die ECC level of the write data based on the ECC level information LVINF. In exemplary embodiments of the inventive concept, the ECC level information LVINF may be represented as an address of memory regions to which the different on-die ECC levels are applied. For example, the address may be a bank address to indicate one bank array among a plurality of bank arrays.

To apply different on-die ECC levels depending on the importance degree of the write data, at least two memory regions among a plurality of memory regions included in the memory cell array 300 may be configured such that a ratio of sizes of the data region and the parity region may be different with respect to the at least two memory regions. The configurations for implementing the plurality of on-die ECC levels may be fixed or variable.

In exemplary embodiments of the inventive concept, the semiconductor memory device 200 may have fixed configurations to apply a plurality of on-die ECC levels. In this case, the semiconductor memory device 200 may provide information CNFINF on the fixed configurations to the memory controller 100, and the memory controller 100 may determine an address corresponding to the write data, for example, a bank address, based on the information CNFINF.

In exemplary embodiments of the inventive concept, the semiconductor memory device 200 may have variable configurations to apply a plurality of on-die ECC levels. In this case, the semiconductor memory device 200 may set the variable configuration based on the information CNFINF provided from the memory controller 100, and the memory controller 100 may determine an address corresponding to the write data, for example, a bank address, based on the information CNFINF.

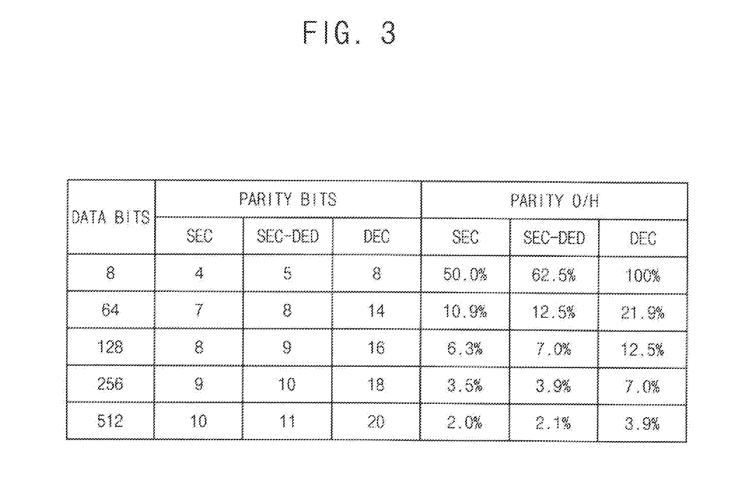

FIG. 3 is a diagram for describing on-die ECC levels according to data bits and parity bits according to an exemplary embodiment of the inventive concept.

In FIG. 3, SEC represents single error correction, DED represents double error detection, and DEC represents double error correction. FIG. 3 illustrates parity bits and corresponding size overheads of the parity bits (PARITY O/H). The parity bits correspond to a Hamming code or an extended Hamming code. The size overhead of the parity bits correspond to a ratio of the parity bits of the parity data corresponding to the write data to the data bits of the write data. The cases in FIG. 3 are non-limiting examples. For example, the parity bit number and the size overhead may be determined differently if Bose-Chaudhuri-Hocquenghem (BCH) code, Reed-Solomon code, etc. are used.

As illustrated in FIG. 3, as the parity bit number is increased with respect to the same data bit number, e.g., as the ratio of the parity bit number to the data bit number is increased, a capability of error detection and correction is increased. As the data bit number is increased with respect to the same capability of error detection and correction, the corresponding parity bit number is increased but the ratio of the parity bit number to the data bit number is decreased.

As such, the error detection capability and/or the error correction capability may be increased as the ratio of the parity bit number to the corresponding data bit number is increased. As a result, the on-die ECC level may be raised as the ratio of the parity bit number to the corresponding data bit number is increased.

A fixed on-die ECC level is applied in conventional schemes. In this case, memory resources may be wasted and a size of the semiconductor memory device may be increased if the on-die ECC level is set higher than necessary. In contrast, the error detection and correction capability may be degraded and performance of the semiconductor memory device may be degraded if the on-die ECC level is set lower than necessary.

On other hand, the semiconductor memory device, the memory system, and the method of controlling an on-die ECC according to exemplary embodiments of the inventive concept may reduce a size of the semiconductor memory device and enhance efficiency of the on-die ECC by applying different on-die ECC levels depending on an importance degree of write data.

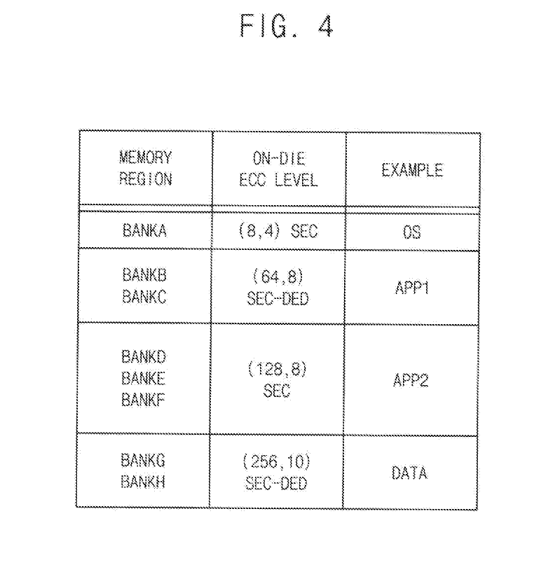

FIG. 4 is a diagram illustrating an example of setting on-die ECC levels according to an exemplary embodiment of the inventive concept.

Referring to FIG. 4, a memory cell array of a semiconductor memory device may include a plurality of bank arrays as a plurality of memory regions. As a non-limiting example, the memory cell array may include first through eighth bank arrays BANKA˜BANKH. In FIG. 4, a of (a, b) represents a data bit number of unit data of the on-die ECC encoding and decoding, and b of (a, b) represents a corresponding parity bit number. For example, as illustrated in FIG. 4, the first bank array BANKA may be set to a first on-die ECC level [(8, 4) SEC], the second and third bank arrays BANKB and BANKC may be set to a second on-die ECC level [(64, 8) SEC-DED] that is lower than the first on-die ECC level, the fourth, fifth, and sixth bank arrays BANKD, BANKE, and BANKF may be set to a third on-die ECC level [(128, 8) SEC] that is lower than the second on-die ECC level, and the seventh and eighth bank arrays BANKG and BANKH may be set to a fourth on-die ECC level [(256, 10) SEC-DED] that is lower than the third on-die ECC level.

As illustrated in FIG. 4, the first on-die ECC level may be assigned to an operating system (OS), the second on-die ECC level may be assigned to applications APP1 of a first group, the third on-die ECC level may be assigned to applications APP2 of a second group, and the fourth on-die ECC level may be assigned to simple data DATA. As such, a relatively high on-die ECC level may be assigned to important data such as the operating system because a fatal effect on a system may result if an error in the operating system is uncorrectable. In contrast, a relatively low on-die ECC level may be assigned to simple data such as image data. The size of the semiconductor memory device may be reduced and efficiency of the on-die ECC may be enhanced by applying different on-die ECC levels depending on the importance degree of the write data.

FIG. 4 shows an example where a memory region corresponds to a bank array, but the inventive concept is not limited thereto. For example, the adaptive on-die ECC may be applied by units of memory blocks in each bank array, or by units of pseudo-channels in a high bandwidth memory (HBM).

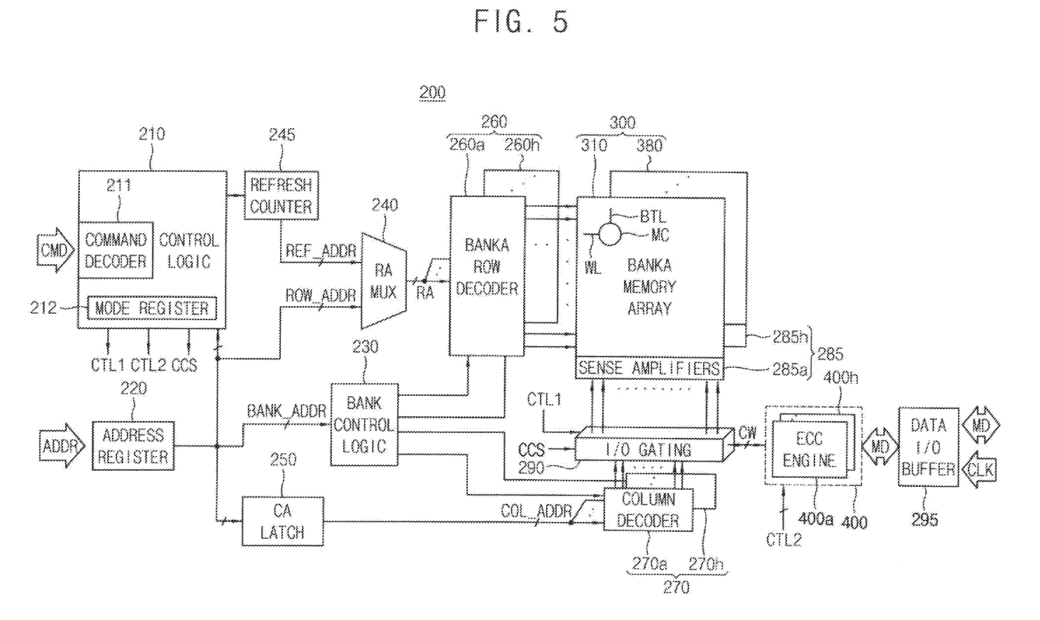

FIG. 5 is a block diagram illustrating a semiconductor memory device according to an exemplary embodiment of the inventive concept.

Referring to FIG. 5, a semiconductor memory device 200 may include a control logic circuit 210, an address register 220, a bank control logic 230, a refresh counter 245, a row address multiplexer 240, a column address latch 250, a row decoder 260, a column decoder 270, the memory cell array 300, a sense amplifier unit 285, an I/O gating circuit block 290, the ECC circuit 400, and a data I/O buffer 295.

The ECC circuit 400 includes first through eighth ECC engines 400a˜400h, and the I/O gating circuit block 290 includes a plurality of I/O gating circuits corresponding to a plurality of bank arrays.

The memory cell array 300 includes first through eighth bank arrays 310˜380. The row decoder 260 includes first through eighth bank row decoders 260a˜260h respectively coupled to the first through eighth bank arrays 310˜380, the column decoder 270 includes first through eighth bank column decoders 270a˜270h respectively coupled to the first through eighth bank arrays 310˜380, and the sense amplifier unit 285 includes first through eighth bank sense amplifiers 285a˜285h respectively coupled to the first through eighth bank arrays 310˜380. The first through eighth bank arrays 310˜380, the first through eighth bank row decoders 260a˜260h, the first through eighth bank column decoders 270a˜270h, and the first through eighth bank sense amplifiers 285a˜285h may form first through eighth banks. Each of the first through eighth bank arrays 310˜380 includes a plurality of memory cells MC formed at intersections of a plurality of word-lines WL and a plurality of bit-line BTL.

The address register 220 receives the address ADDR including a bank address BANK_ADDR, a row address ROW_ADDR, and a column address COL_ADDR from the memory controller 100. The address register 220 provides the received bank address BANK_ADDR to the bank control logic 230, provides the received row address ROW_ADDR to the row address multiplexer 240, and provides the received column address COL_ADDR to the column address latch 250.

The bank control logic 230 generates bank control signals in response to the bank address BANK_ADDR. One of the first through eighth bank row decoders 260a˜260h corresponding to the bank address BANK_ADDR is activated in response to the bank control signals, and one of the first through eighth bank column decoders 270a—270h corresponding to the bank address BANK_ADDR is activated in response to the bank control signals.

The row address multiplexer 240 receives the row address ROW_ADDR from the address register 220, and receives a refresh row address REF_ADDR from the refresh counter 245. The row address multiplexer 240 selectively outputs the row address ROW_ADDR or the refresh row address REF_ADDR as a row address RA. The row address RA that is output from the row address multiplexer 240 is applied to the first through eighth bank row decoders 260a—260h.

The activated one of the first through eighth bank row decoders 260a˜260h decodes the row address RA that is output from the row address multiplexer 240, and activates a word-line of a bank array corresponding to the row address RA. For example, the activated bank row decoder applies a word-line driving voltage to the word-line corresponding to the row address RA. The column address latch 250 receives the column address COL_ADDR from the address register 220, and temporarily stores the received column address COL_ADDR. In exemplary embodiments of the inventive concept, in a burst mode, the column address latch 250 generates column addresses that increment from the received column address COL_ADDR. The column address latch 250 applies the temporarily stored or generated column address to the first through eighth bank column decoders 270a˜270h.

The activated one of the first through eighth bank column decoders 270a˜270h activates a sense amplifier corresponding to the bank address BANK_ADDR and the column address COL_ADDR through the I/O gating circuit block 290. Each of the I/O gating circuits in the I/O gating circuit block 290 includes circuitry for gating input/output data, and further includes read data latches for storing data that is output from the first through eighth bank arrays 310˜380 and write drivers for writing data to the first through eighth bank arrays 310˜380.

A codeword CW read from one bank array of the first through eighth bank arrays 310˜380 is sensed by a sense amplifier coupled to the one bank array from which the data is to be read, and is stored in the read data latches. The codeword CW stored in the read data latches may be provided to the memory controller 100 via the data I/O buffer 295 after ECC decoding is performed on the codeword CW by a corresponding ECC engine. The data MD to be written in one bank array of the first through eighth bank arrays 310˜380 may be provided to the data I/O buffer 295 from the memory controller 100, and written in the one bank array by the write drivers after an ECC encoding is performed on the data MD by a corresponding ECC engine.

The data I/O buffer 295 may provide the data MD from the memory controller 100 to the ECC circuit 400 in a write operation of the semiconductor memory device 200, based on the clock signal CLK, and may provide the data MD from the ECC circuit 400 to the memory controller 100 in a read operation of the semiconductor memory device 200.

The ECC circuit 400, in the write operation, generates parity data (e.g., parity bits) based on the main data MD from the data I/O buffer 295, and provides the I/O gating circuit block 290 with the codeword CW including the main data MD and the parity bits. The I/O gating circuit block 290 may write the codeword CW in one bank array.

In addition, the ECC circuit 400, in the read operation, may receive the codeword CW, read from one bank array, from the I/O gating circuit block 290. The ECC circuit 400 may perform an ECC decoding on the data MD based on the parity bits in the codeword CW, may correct a single bit error or double bit error in the data MD, and may provide corrected main data to the data I/O buffer 295.

The control logic circuit 210 may control operations of the semiconductor memory device 200. For example, the control logic circuit 210 may generate control signals for the semiconductor memory device 200 to perform a write operation or a read operation. The control logic circuit 210 includes a command decoder 211 that decodes the command CMD received from the memory controller 100 and a mode register 212 that sets an operation mode of the semiconductor memory device 200. For example, a value of the mode register 212 may indicate the operation mode.

For example, the command decoder 211 may generate the control signals corresponding to the command CMD by decoding a write enable signal (/WE), a row address strobe signal (/RAS), a column address strobe signal (/CAS), a chip select signal (/CS), etc. The control logic circuit 210 may generate a column control signal CCS and a first control signal CTL1 to control the I/O gating circuit block 290 and a second control signal CTL2 to control the ECC circuit 400.

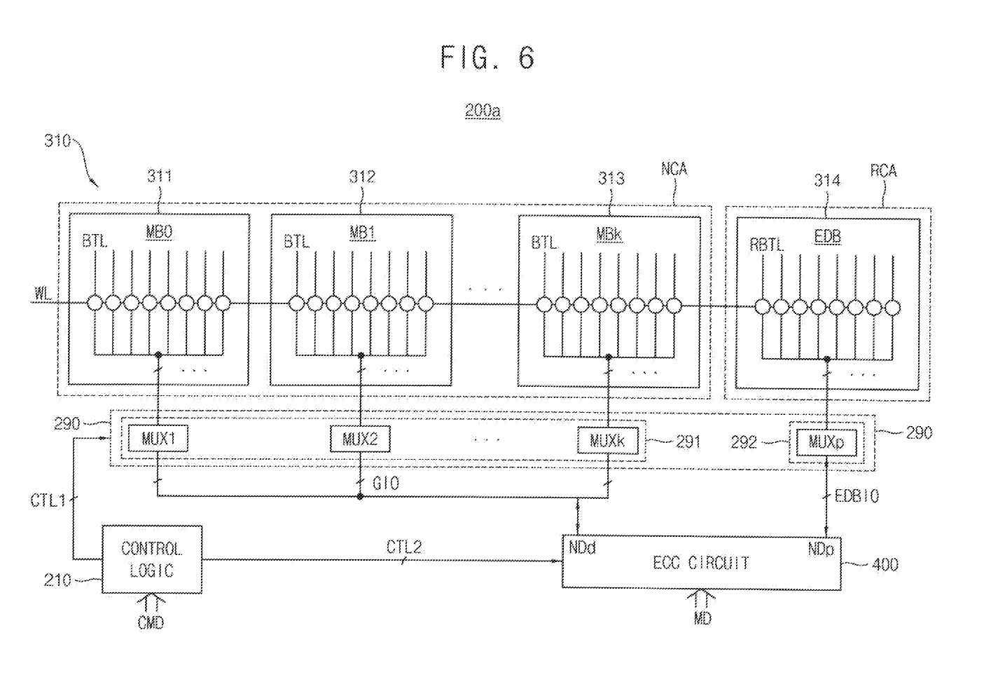

FIG. 6 illustrates a portion of the semiconductor memory device of FIG. 5 according to an exemplary embodiment of the inventive concept.

Referring to FIG. 6, a semiconductor memory device 200a may include the control logic 210, the first bank array 310, the I/O gating circuit 290, and the ECC circuit 400. The first bank array 310 may include a normal cell array NCA and a redundancy cell array RCA. The normal cell array NCA may include a plurality of first memory blocks MB0˜MBk, e.g., 311˜313, and the redundancy cell array RCA may include at least a second memory block EDB, e.g., 314. The first memory blocks 311˜313 are memory blocks determining a memory capacity of the semiconductor memory device 200a. The second memory block 314 is for ECC and/or redundancy repair. Since the second memory block 314 for ECC and/or redundancy repair is used for ECC, data line repair, or block repair to repair one or more failed cells generated in the first memory blocks 311˜313, the second memory block 314 is also referred to as an EDB block.

In each of the first memory blocks 311˜313, a plurality of first memory cells are arrayed in rows and columns. In the second memory block 314, a plurality of second memory cells are arrayed in rows and columns.

In the first memory blocks 311˜313, rows may be formed, for example, of 8K word lines WL, and columns may be formed, for example, of 1K bit lines BTL. The first memory cells connected to intersections of the word lines WL and the bit lines BTL may be dynamic memory cells or resistive type memory cells. In the second memory block 314, rows may be formed, for example, of 8K word lines WL, and columns may be formed, for example, of 1K bit lines BTL. The second memory cells connected to intersections of the word lines WL and bit lines RBTL may be dynamic memory cells or resistive type memory cells.

The I/O gating circuit 290 may include a first switching circuit 291 connected to the first memory blocks 311˜313 and a second switching circuit connected to the second memory block 314. In the semiconductor memory device 200a, bit lines corresponding to data of a burst length (BL) may be simultaneously accessed to support the BL indicating the maximum number of column positions that is accessible. For example, the BL may be set to 8. In this case, each of the bit lines BTL and RBTL may be connected to a corresponding one of column selectors MUX1˜MUXk and MUXp.

The ECC circuit 400 may be connected to the first and second switching circuits 291 and 292 through first data lines GIO and second data lines EDBIO, respectively. The first data lines GIO may be connected to data nodes NDd of the ECC circuit 400 and the second data lines EDBIO may be connected to parity nodes NDp of the ECC circuit 400.

The control logic circuit 210 may decode the command CMD to generate the first control signal CTL1 for controlling the first and second switching circuits 291 and 292 and the second control signal CTL2 for controlling the ECC circuit 400.

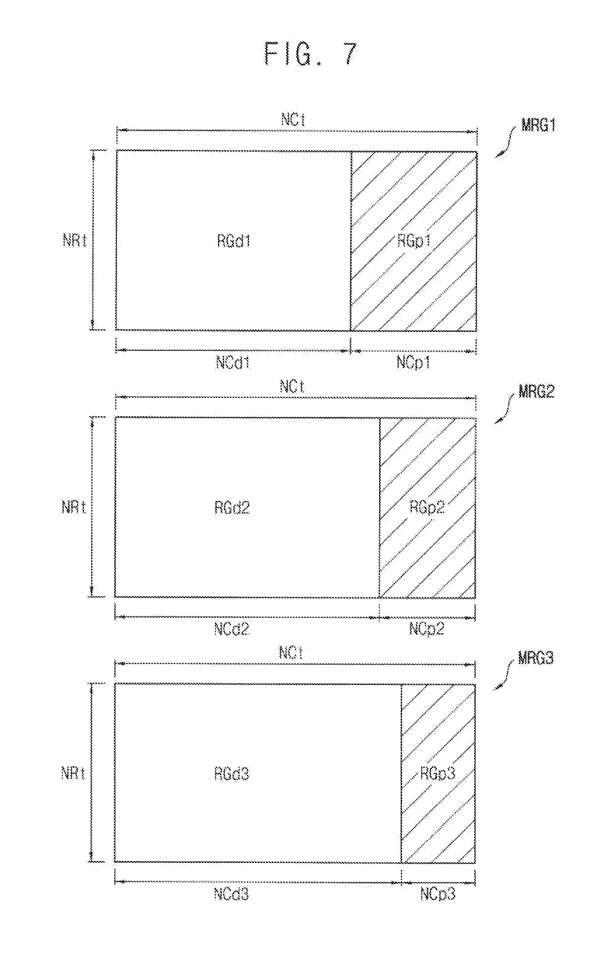

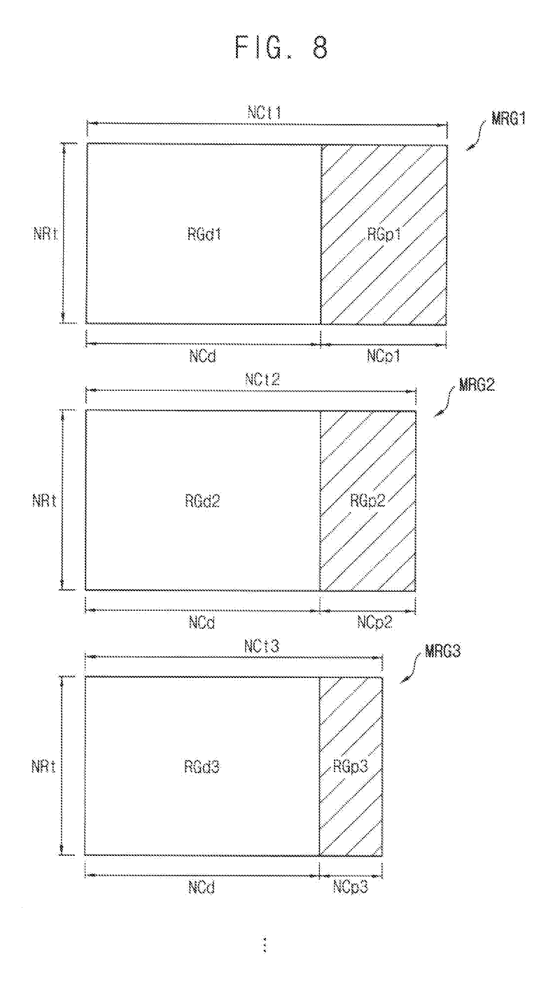

FIGS. 7 and 8 are diagrams illustrating a fixed configuration of a memory cell array for implementing a plurality of on-die ECC levels according to exemplary embodiments of the inventive concept.

Some memory regions MRG1˜MRG3 included in a memory array are illustrated in FIGS. 7 and 8 and the other components are omitted for convenience of illustration. The numbers of the first data lines GIO and the second data lines EDBIO in FIG. 6 may be determined depending on column sizes of a data region and a parity region in each of the memory regions MRG1˜MRG3. In exemplary embodiments of the inventive concept, the memory regions MRG1˜MRG3 may be bank arrays.

Referring to FIGS. 7 and 8, each of the memory regions MRG1˜MRG3 may include a data region in which write data are stored and a parity region in which parity data are stored. The first memory region MRG1 may include a first data region RGd1 and a first parity region RGp1, the second memory region MRG2 may include a second data region RGd2 and a second parity region RGp2, and the third memory region MRG3 may include a third data region RGd3 and a third parity region RGp3.

Each of the memory regions MRG1˜MRG3 has a configuration corresponding to one of a plurality of on-die ECC levels. For this, the memory regions MRG1˜MRG3 may be implemented such that a ratio of a size of the data region and a size of the parity region is different with respect to the memory regions MRG1˜MRG3. The size of a region indicates a number of memory cells in the region or a bit number of data that may be stored in the region.

Even though FIGS. 7 and 8 illustrate three memory regions having different ratios of the sizes of the data region and the parity region, the memory cell array may instead include two, four, or more memory regions having different size ratios according to setting of the on-die ECC levels.

In exemplary embodiments of the inventive concept, as illustrated in FIG. 7, with respect to the first through third memory regions MRG1˜MRG3, each of an entire row size NRt, an entire column size NCt, a row size NRt of the data region, and a row size NRt of the parity region is substantially identical, and a ratio of a column size NCd1, NCd2, or NCd3 of the data region and a column size NCp1, NCp2, or NCp3 of the parity region is different. In other words, the entire size of each memory region may be substantially identical with respect to the memory regions MRG1˜MRG3 and column sizes of the data region and the parity region may be different with respect to the memory regions MRG1˜MRG3. The column size ratio NCp1/NCd1 of the first data region RGd1 and the first parity region RGp1 may be greater than the column size ratio NCp2/NCd2 of the second data region RGd2 and the second parity region RGp2. The column size ratio NCp2/NCd2 of the second data region RGd2 and the second parity region RGp2 may be greater than the column size ratio NCp3/NCd3 of the third data region RGd3 and the third parity region RGp3. Accordingly, the highest on-die ECC level may be assigned to the first memory region MRG1, the intermediate on-die ECC level may be assigned to the second memory region MRG2, and the lowest on-die ECC level may be assigned to the third memory region MRG3.

In exemplary embodiments of the inventive concept, as illustrated in FIG. 8, with respect to the first through third memory regions MRG1˜MRG3, entire column sizes NCt1, NCt2, or NCt3 are different, each of an entire row size NRt, a row size NRt of the data region, and a row size NRt of the parity region is substantially identical, and a ratio of a column size NCd1, NCd2, or NCd3 of the data region and a column size NCp1, NCp2, or NCp3 of the parity region is different. In other words, the size of the data region may be substantially identical with respect to the memory regions MRG1˜MRG3 and the entire size of the memory region may be different with respect to the memory regions MRG1˜MRG3. The column size ratio NCp1/NCd of the first data region RGd1 and the first parity region RGp1 may be greater than the column size ratio NCp2/NCd of the second data region RGd2 and the second parity region RGp2. The column size ratio NCp2/NCd of the second data region RGd2 and the second parity region RGp2 may be greater than the column size ratio NCp3/NCd of the third data region RGd3 and the third parity region RGp3. Accordingly, the highest on-die ECC level may be assigned to the first memory region MRG1, the intermediate on-die ECC level may be assigned to the second memory region MRG2, and the lowest on-die ECC level may be assigned to the third memory region MRG3.

As such, using the fixed configurations of the memory cell array or the memory regions as described with reference to FIGS. 7 and 8, the different on-die ECC levels may be implemented.

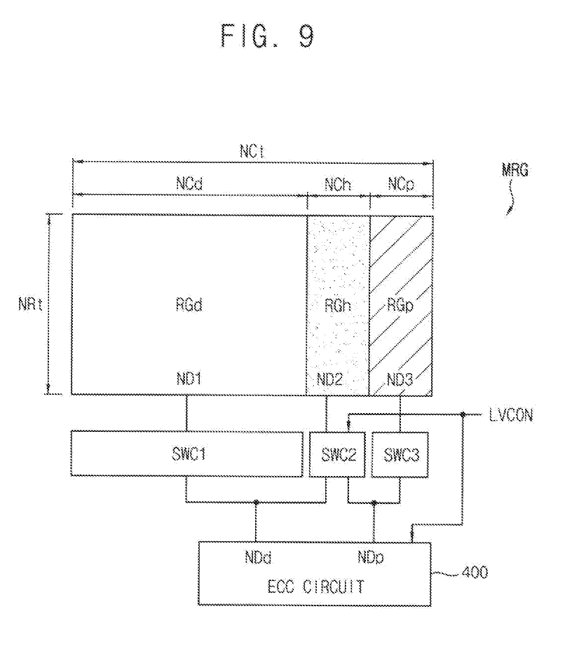

FIG. 9 is a diagram illustrating a variable configuration of a memory cell array for implementing a plurality of on-die ECC levels according to an exemplary embodiment of the inventive concept.

Referring to FIG. 9, a memory region MRG may include a data region RGd, a hybrid region RGh, and a parity region RGp. The data region RGd may be dedicated to store write data and the parity region RGp may be dedicated to store parity data. The hybrid region RGh may be configured to store the write data or the parity data selectively depending on the on-die ECC level assigned to the memory region MRG. In exemplary embodiments of the inventive concept, the memory region MRG may be a bank array.

A first switch circuit SWC1 may be connected between input-output nodes ND1 of the data region RGd and a first portion of data nodes NDd of the ECC circuit 400. A second switch circuit SWC3 may be connected between input-output nodes ND3 of the parity region RGp and a first portion of parity nodes NDp of the ECC circuit 400. A second switch circuit SWC2 may selectively connect input-output nodes ND2 of the hybrid region RGh to a second portion of the parity nodes NDp of the ECC circuit 400 or a second portion of the data nodes NDd of the ECC circuit 400.

When a level control signal LVCON indicates a relatively high on-die ECC level, the second switch circuit SWC2 may connect the input-output nodes ND2 of the hybrid region RGh to the second portion of the parity nodes NDp of the ECC circuit 400 so that the hybrid region RGh may store a portion of the parity data. In contrast, when the level control signal LVCON indicates a relatively low on-die ECC level, the second switch circuit SWC2 may connect the input-output nodes ND2 of the hybrid region RGh to the second portion of the data nodes NDd of the ECC circuit 400 so that the hybrid region RGh may store a portion of the write data.

As a result, a size ratio of the actual parity region to the actual data region may be increased to (NCh+NCp)/NCd when the on-die ECC level is set higher and decreased to NCp/(NCd+NCh) when the on-die ECC level is set lower.

As such, using the variable configurations of the memory cell array or the memory regions as described with reference to FIG. 9, the different on-die ECC levels may be implemented.

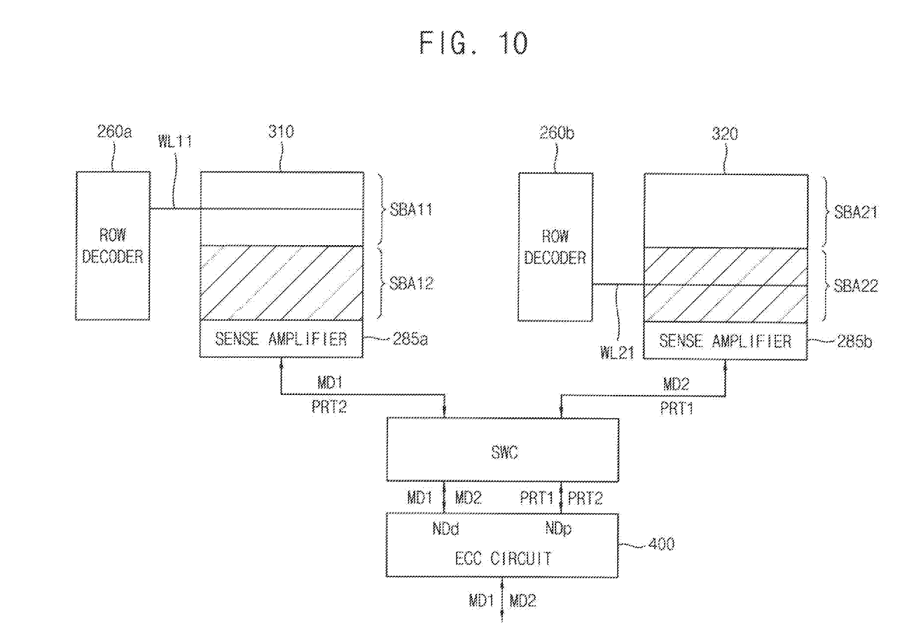

FIG. 10 illustrates a portion of the semiconductor memory device of FIG. 5 according to an exemplary embodiment of the inventive concept.

As an example, FIG. 10 illustrates the first bank array 310, the second bank array 320, associated circuits 260a, 260b, 285a, and 285b (which are described with reference to FIG. 5), a switch circuit SWC, and the ECC circuit 400.

Referring to FIG. 10, first write data MD1 is stored in a first sub array SBA11 of the first bank array 310 and first parity data PRT1 corresponding to the first write data MD1 is stored in a second sub array SBA22 of the second bank array 320. In this case, as illustrated in FIG. 10, a word line WL11 of the first bank array 310 and a word line WL21 of the second bank array 320 may be enabled simultaneously. In a similar way, second write data MD2 is stored in a first sub array SBA21 of the second bank array 320 and second parity data PRT2 corresponding to the second write data MD2 is stored in a second sub array SBA12 of the first bank array 310. In this case, even though not illustrated in FIG. 10, one word line of the first bank array 310 and one word line of the second bank array 320 may be enabled simultaneously.

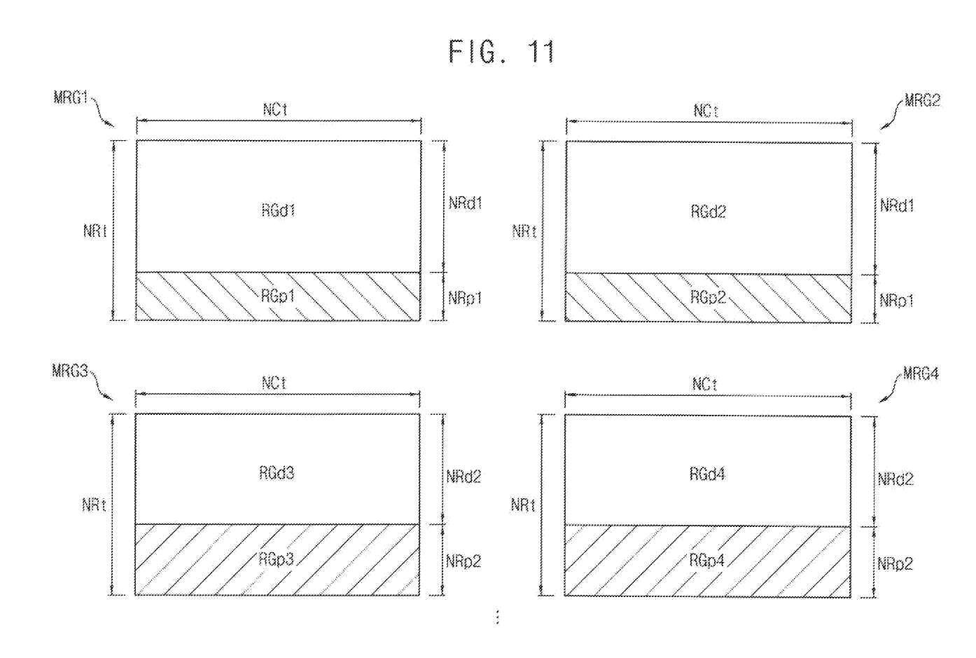

As such, the write data may be stored in one memory bank and the corresponding parity data may be stored in another memory bank. In this case, as will be described below with reference to FIGS. 11, 12, and 13, the data region and the parity region may be defined by dividing rows of the bank array.

FIGS. 11, 12, and 13 illustrate examples where the memory region is divided on a row basis whereas FIGS. 7, 8, and 9 illustrate examples where the memory region is divided on a column basis. Hereinafter, the repeat descriptions of elements already described with reference to FIGS. 7, 8, and 9 may be omitted.

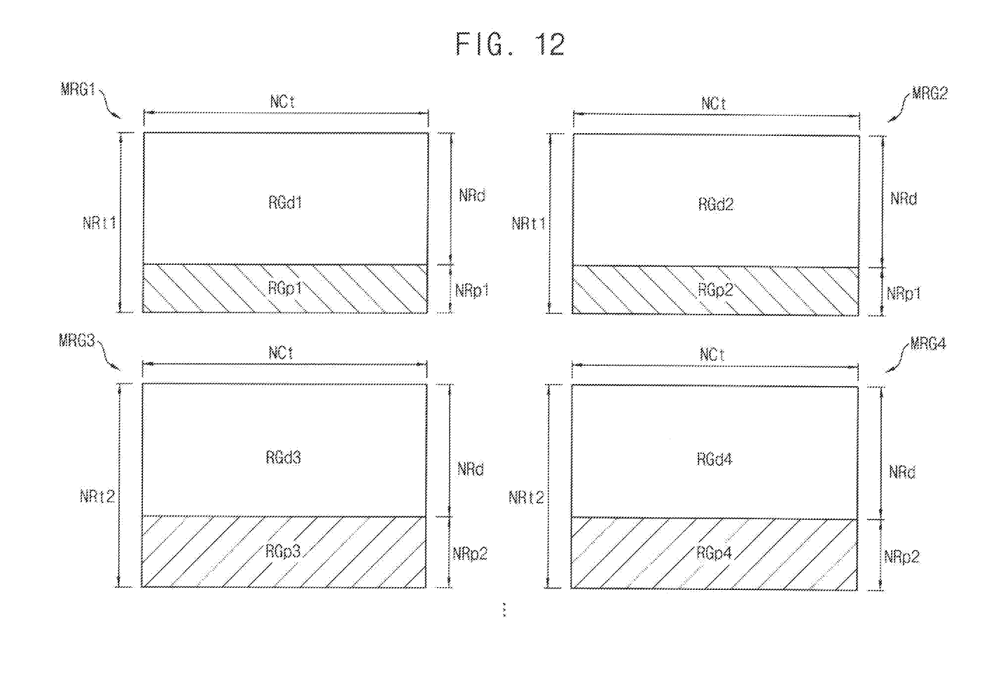

FIGS. 11 and 12 are diagrams illustrating a fixed configuration of a memory cell array for implementing a plurality of on-die ECC levels according to exemplary embodiments of the inventive concept.

Referring to FIGS. 11 and 12, each of the memory regions MRG1˜MRG4 may include a data region in which write data are stored and a parity region in which parity data are stored. The first memory region MRG1 may include the first data region RGd1 and the first parity region RGp1, the second memory region MRG2 may include the second data region RGd2 and the second parity region RGp2, the third memory region MRG3 may include the third data region RGd3 and the third parity region RGp3, and the fourth memory region MRG4 may include a fourth data region RGd4 and a fourth parity region RGp4.

Even though FIGS. 11 and 12 illustrate a first memory region pair MRG1 and MRG2 and a second memory region pair MRG3 and MRG4 having different ratios of the sizes of the data region and the parity region, the memory cell array may include one, three, or more memory region pairs having different size ratios according to setting of the on-die ECC levels.

In exemplary embodiments of the inventive concept, as illustrated in FIG. 11, with respect to the first through fourth memory regions MRG1˜MRG4, each of an entire row size NRt, an entire column size NCt, a column size NCt of the data region, and a column size NCt of the parity region is substantially identical, and a ratio of a row size NRd1 or NRd2 of the data region and a row size NRp1 or NRp2 of the parity region is different. In other words, the entire size of each memory region may be substantially identical with respect to the memory regions MRG1˜MRG4 and row sizes of the data region and the parity region may be different with respect to the memory regions MRG1˜MRG4. The row size ratio NRp1/NRd1 of the first and second data regions RGd1 and RGd2 and the first and second parity regions RGp1 and RGp3 may be smaller than the row size ratio NRp2/NRd2 of the third and fourth data regions RGd3 and RGd4 and the third and fourth parity regions RGp3 and RGp4. Accordingly, the lower on-die ECC level may be assigned to the first and second memory regions MRG1 and MRG2, and the higher on-die ECC level may be assigned to the third and fourth memory region MRG3 and MRG4.

In exemplary embodiments of the inventive concept, as illustrated in FIG. 12, with respect to the first through fourth memory regions MRG1˜MRG4, entire row sizes NRt1 and NRt2 of the bank array are different, each of an entire column size NCt, a column size NCt and a row size NRt of the data region, and a column size NCt of the parity region is substantially identical, and a ratio of a row size NRd of the data region and a row size NRp1 or NRp2 of the parity region is different. In other words, the size of the data region may be identical with respect to the memory regions MRG1˜MRG4 and the entire row sizes NRt1 and NRt2 may be different with respect to the memory regions MRG1˜MRG4. The row size ratio NRp1/NRd of the first and second data regions RGd1 and RGd2 and the first and second parity regions RGp1 and RGp3 may be smaller than the row size ratio NRp2/NRd of the third and fourth data regions RGd3 and RGd4 and the third and fourth parity regions RGp3 and RGp4. Accordingly, the lower on-die ECC level may be assigned to the first and second memory regions MRG1 and MRG2, and the higher on-die ECC level may be assigned to the third and fourth memory region MRG3 and MRG4.

As such, using the fixed configurations of the memory cell array or the memory regions as described with reference to FIGS. 11 and 12, the different on-die ECC levels may be implemented.

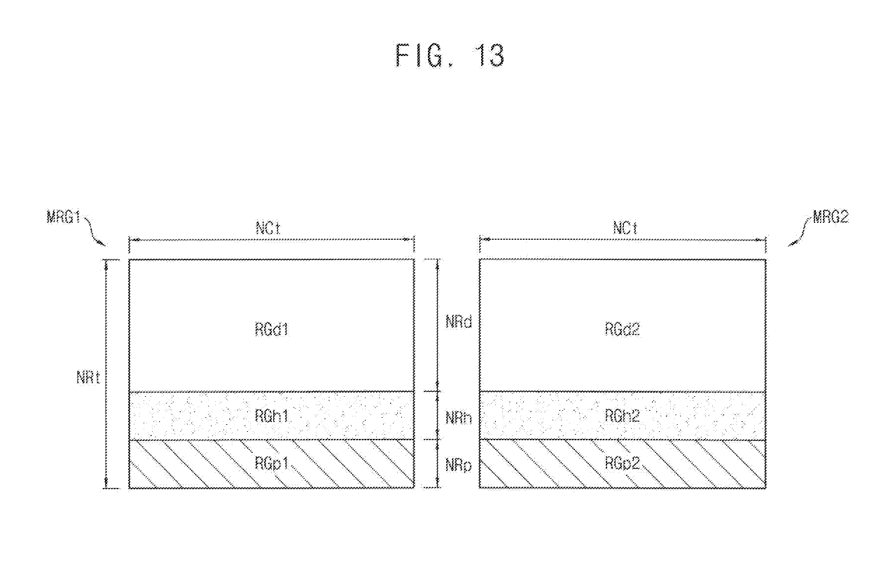

FIG. 13 is a diagram illustrating a variable configuration of a memory cell array for implementing a plurality of on-die ECC levels according to an exemplary embodiment of the inventive concept.

Referring to FIG. 13, the memory regions MRG1 and MRG2 may include data regions RGd1 and RGd2, hybrid regions RGh1 and RGh2, and parity regions RGp1 and RGp2. The data regions RGd1 and RGd2 may be dedicated to store write data and the parity regions RGp1 and RGp2 may be dedicated to store parity data. The hybrid regions RGh1 and RGh2 may be configured to store the write data or the parity data selectively depending on the on-die ECC level assigned to the memory regions MRG1 and MRG2. In exemplary embodiments of the inventive concept, each of the memory regions MRG1 and MRG2 may be a bank array.

When the memory regions MRG1 and MRG2 are set to a relatively high on-die ECC level, the hybrid regions RGh1 and RGh2 may be configured to store the parity data. In contrast, when the memory regions MRG1 and MRG2 are set to a relatively low on-die ECC level, the hybrid regions RGh1 and RGh2 may be configured to store the write data.

As a result, a size ratio of the actual parity region to the actual data region may be increased to (NRh+NRp)/NRd when the on-die ECC level is set higher and decreased to NRp/(NRd+NRh) when the on-die ECC level is set lower.

As such, using the variable configurations of the memory cell array or the memory regions as described with reference to FIG. 13, the different on-die ECC levels may be implemented.

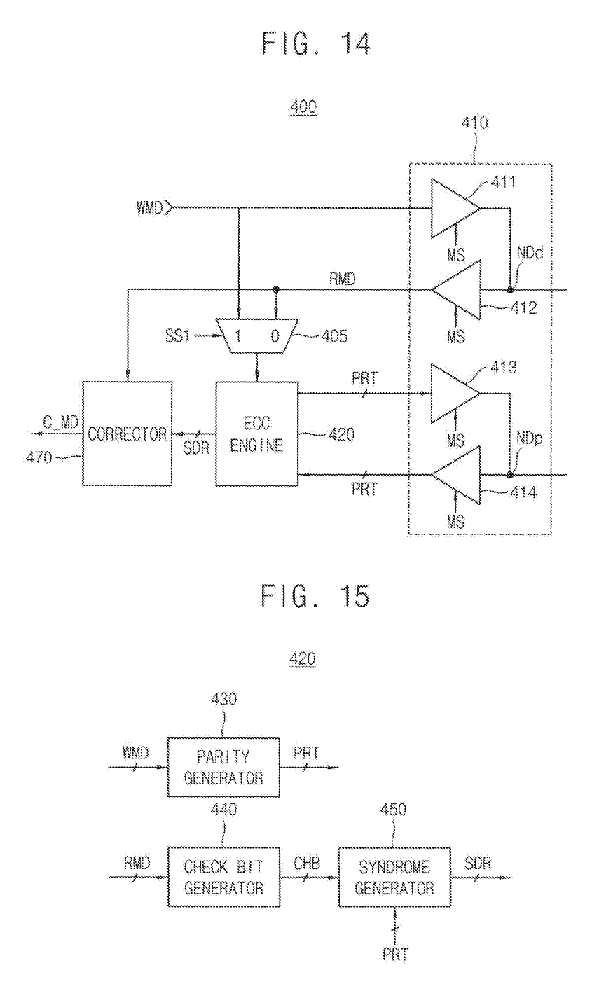

FIG. 14 is a diagram illustrating an ECC circuit included in the semiconductor memory device of FIG. 5 according to an exemplary embodiment of the inventive concept.

Referring to FIG. 14, the ECC circuit 400 may include a multiplexer 405, an ECC engine 420, a buffer unit 410, and a data corrector 470. The buffer unit 410 may include first through fourth buffers 411˜414.

The multiplexer 405, in a write operation of the semiconductor memory device 200a, provides write data WMD to the ECC engine 420 in response to a first selection signal SS1. The multiplexer 405, in a read operation of the semiconductor memory device 200a, provides read data RMD from the buffer 412 to the ECC engine 420 in response to the first selection signal SS1.

The buffers 411 and 413 may be enabled in the write operation in response to a mode signal MS and provide the write data WMD and parity data PRT to the I/O gating circuit 290 through data nodes NDd and parity nodes NDp, respectively. The buffers 412 and 414 may be enabled in the read operation in response to the mode signal MS, the buffer 412 may provide the read data RMD to the multiplexer 405 and the data corrector 470 through the data nodes NDd, and the buffer 414 may provide the parity data PRT to the ECC engine 420 through the parity nodes NDp.

The ECC engine 420, in the write operation, may perform an ECC encoding on the write data WMD to provide the parity data PRT to the buffer 413. The ECC engine 420, in the read operation, may perform an ECC decoding on the read data RMD from the multiplexer 405 based on the parity data PRT from the buffer 414 to provide syndrome data SDR to the data corrector 470.

The data corrector 470 corrects an error bit in the read data RMD based on the syndrome data SDR from the ECC engine 420 to provide a corrected main data C MD.

In FIG. 14, the first selection signal SS1 and the mode signal MS may be included in the second control signal CTL2 provided from the control logic circuit 210 in FIG. 5.

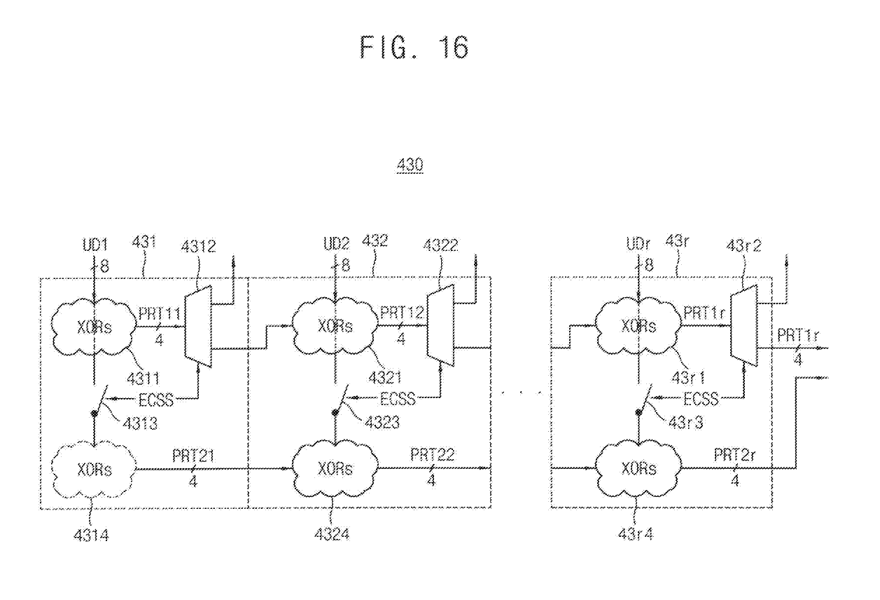

FIG. 15 is a block diagram illustrating an ECC engine included in the ECC circuit of FIG. 14 according to an exemplary embodiment of the inventive concept.

Referring to FIG. 15, the ECC engine 420 may include a parity generator 430, a check bit generator 440, and a syndrome generator 450.

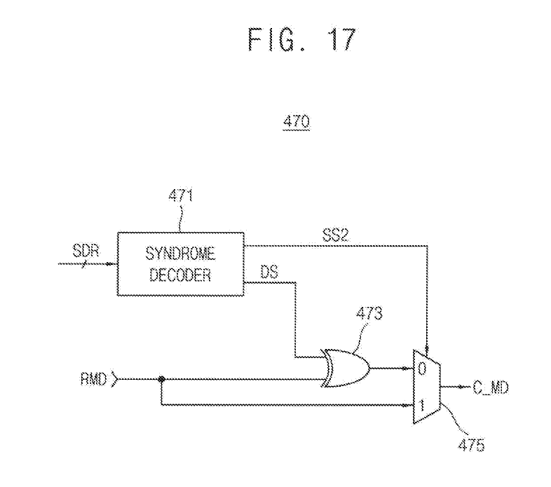

The parity generator 430 may generate the parity data PRT based on the write data WMD using an array of exclusive OR gates. The parity generator 430 may include a plurality of sub generators that operate as a whole or individually, as will be described below with reference to FIG. 16.

The check bit generator 440 may generate check bits CHB based on the read main data RMD. The check bit generator 440 may include a plurality of sub generators that operate as a whole or individually.

The syndrome generator 450 may generate the syndrome data SDR based on the check bits CHB and the parity data PRT from the buffer 414. The syndrome generator 450 may include a plurality of sub generators. A number of the sub generators, which are activated, may be reconfigurable (adjustable or changeable) depending on the assigned on-die ECC level.

FIG. 16 is a diagram illustrating a parity generator included in the ECC engine of FIG. 15 according to an exemplary embodiment of the inventive concept.

Referring to FIG. 16, the parity generator 430 may include a plurality of parity sub generators 431˜43r, where r is a natural number greater than two.

The parity sub generators 431˜43r may be connected to one another and operate as a whole in a first engine configuration mode, or may be separated from one another and operate individually in a second engine configuration mode.

Each of the parity sub generators 431˜43r may include a corresponding one of a first set of XOR modules 4311˜43r1, a corresponding one of demultiplexers 4312˜43r2, a corresponding one of switches 4313˜43r3, and a corresponding one of a second set of XOR modules 4314˜43r4.

Each of the first set of XOR modules 4311˜43r1 may perform an XOR operation on a corresponding one of sub data UD1˜UDr, which constitute the main data MD (e.g., write data WMD) and may generate a corresponding one of first partial parity data PRT11˜PRT1r. Each of the switches 4313˜43r3 may be connected between a corresponding one of the first set of XOR modules 4311˜43r1 and a corresponding one of the second set of XOR modules 4314˜43r4, may provide a corresponding one of sub data UD1˜UDr to a corresponding one of the second set of XOR modules 4314˜43r4 in the first engine configuration mode, and may be opened in the second configuration mode, in response to the engine configuration selection signal ECSS. The second set of XOR modules 4314˜43r4 may be sequentially connected to one another in the first engine configuration mode. Each of the second set of XOR modules 4314˜43r4 performs an XOR operation on a corresponding one of the sub data UD1˜UDr and may generate a corresponding one of second partial parity data PRT21˜PRT2r sequentially.

Each of the demultiplexers 4312˜43r2 may provide a corresponding one of the first partial parity data PRT11˜PRT1r to a first path in the first engine configuration mode when a relatively high on-die ECC level is assigned, and may provide a corresponding one of the first partial parity data PRT11˜PRT1r to a second path in the second engine configuration mode when a relatively low on-die ECC level is assigned, in response to the engine configuration selection signal ECSS. In the first engine configuration mode, the parity sub generators 431˜43r may be sequentially connected to one another through the first path of each of the parity sub generators 431˜43r. In the second engine configuration mode, the parity sub generators 431˜43r may be separated from one another and provide the first partial parity data PRT11˜PRT1r individually.

The engine configuration selection signal ECSS may be included in the second control signal CTL2 provided from the control logic circuit 210 in FIG. 5.

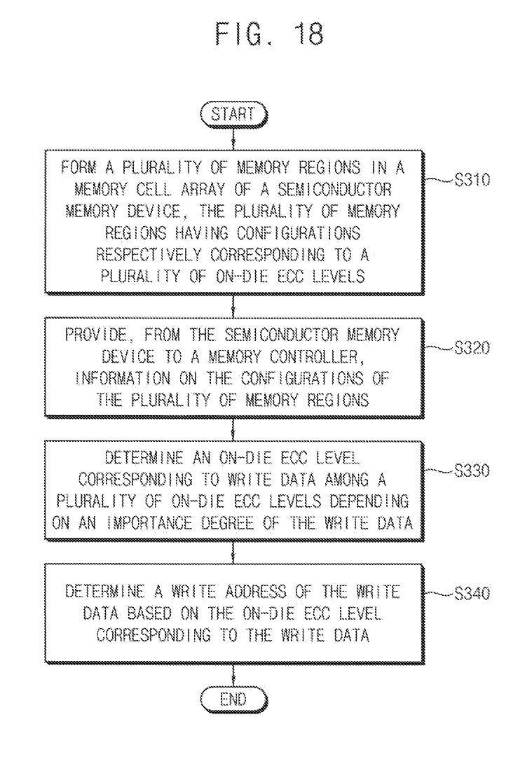

FIG. 17 is a diagram illustrating a data corrector included in the ECC circuit of FIG. 14 according to an exemplary embodiment of the inventive concept.

Referring to FIG. 17, the data corrector 470 may include a syndrome decoder 471, a bit inverter 473, and a selection circuit 475 which is implemented by a multiplexer.

The syndrome decoder 471 may decode the syndrome data SDR to generate a decoding signal DS and a second selection signal SS2. The decoding signal DS may indicate a position of at least one error bit and the second selection signal SS2 may have a logic level depending on a number of the at least one error bit. The bit inverter 473 may invert the at least one error bit in response to the decoding signal DS. The selection circuit 475 may select one of the read data RMD and an output of the bit inverter 473 to provide the corrected main data C_MD in response to the second selection signal SS2.

The syndrome decoder 471 may output the second selection signal SS2 with a first logic level (e.g., logic high level) when a number of the at least one error bit in the read data RMD exceeds the error correction capability of the ECC based on the syndrome data SDR. The selection circuit 475 may provide the read data RMD as the corrected main data C_MD in response to the second selection signal SS2 having the first logic level. The syndrome decoder 471 may output the decoding signal DS with the first logic level and output the second selection signal SS2 with a second logic level (e.g., logic low level) when a number of the at least one error bit in the read data RMD is within the error correction capability of the ECC based on the syndrome data SDR. The bit inverter 473 may invert the at least one error bit in response to the decoding signal DS having the first logic level. The selection circuit 475 may provide the output of the bit inverter 473 as the corrected main data C_MD in response to the second selection signal SS2 having the second logic level.

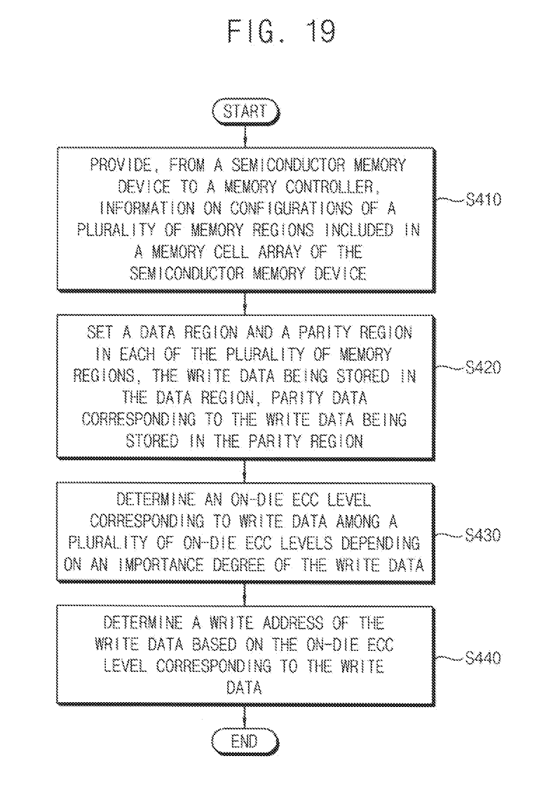

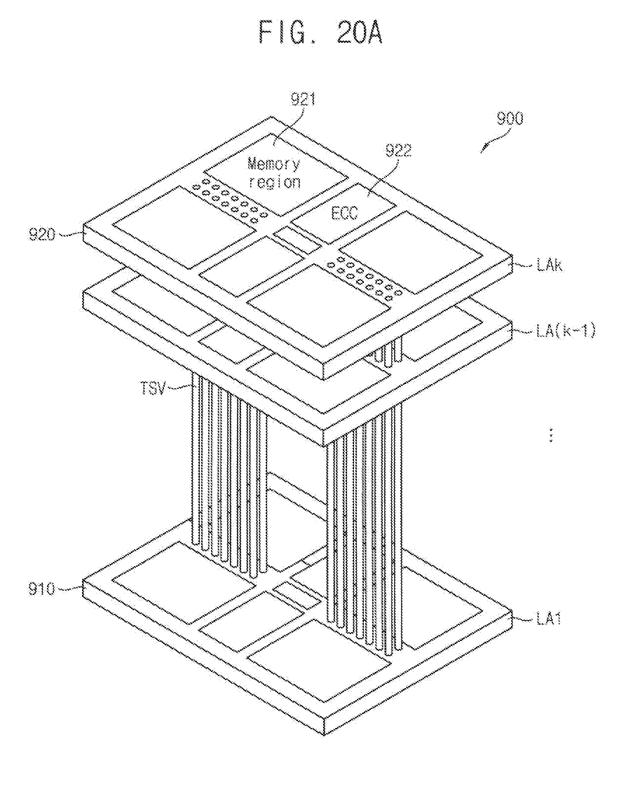

FIGS. 18 and 19 are flowcharts illustrating a method of controlling on-die ECC according to exemplary embodiments of the inventive concept.

Referring to FIG. 18, a plurality of memory regions are formed in a memory cell array of a semiconductor memory device, such that the plurality of memory regions have configurations respectively corresponding to a plurality of on-die ECC levels (S310). In this case, the semiconductor memory device may have fixed configurations as described above to implement the plurality of on-die ECC levels. Information on the configurations of the plurality of memory regions is provided from the semiconductor memory device to a memory controller (S320). The memory controller determines an on-die ECC level corresponding to write data among the plurality of on-die ECC levels depending on an importance degree of the write data (S330) and determines a write address of the write data based on the on-die ECC level corresponding to the write data (S340).

Referring to FIG. 19, information on configurations of a plurality of memory regions included in a memory cell array of the semiconductor memory device is provided from a semiconductor memory device to a memory controller (S410). In this case, the semiconductor memory device may have variable configurations as described above to implement a plurality of on-die ECC levels. The semiconductor memory device sets a data region and a parity region in each of the plurality of memory regions, where the write data are stored in the data region and parity data corresponding to the write data are stored in the parity region (S420). The memory controller determines an on-die ECC level corresponding to write data among the plurality of on-die ECC levels depending on an importance degree of the write data (S430) and determines a write address of the write data based on the on-die ECC level corresponding to the write data (S440).

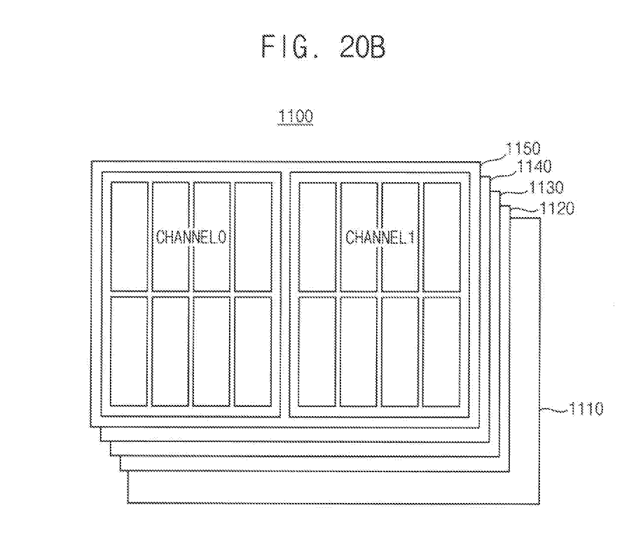

FIGS. 20A and 20B are diagrams illustrating a stacked memory device according to exemplary embodiments of the inventive concept.

Referring to FIG. 20, a semiconductor memory device 900 includes first through kth semiconductor integrated circuit layers LA1 through LAk, in which the lowest first semiconductor integrated circuit layer LA1 is assumed to be an interface or control chip and the other semiconductor integrated circuit layers LA2 through LAk are assumed to be slave chips including core memory chips. The slave chips may form a plurality of memory ranks.

The first through kth semiconductor integrated circuit layers LA1 through LAk may transmit and receive signals between the layers by through-substrate vias TSVs (e.g., through-silicon vias). The lowest first semiconductor integrated circuit layer LA1 may communicate with an external memory controller through a conductive structure formed on an external surface.

Each of a first semiconductor integrated circuit layer 910 through a kth semiconductor integrated circuit layer 920 may include memory regions 921 and peripheral circuits 922 for driving the memory regions 921. For example, the peripheral circuits 922 may include a row-driver for driving wordlines of a memory, a column-driver for driving bit lines of the memory, a data input-output circuit for controlling input-output of data, a command buffer for receiving a command from an outside source and buffering the command, and an address buffer for receiving an address from an outside source and buffering the address.

The first semiconductor integrated circuit layer 910 may further include a control circuit. The control circuit may control access to the memory region 921 based on a command and an address signal from a memory controller and may generate control signals for accessing the memory region 921.

At least one of the semiconductor integrated circuit layers LA2 through LAk corresponding to slave layers may include an ECC circuit 922 configured to on-die ECC according to an exemplary embodiment of the inventive concept.

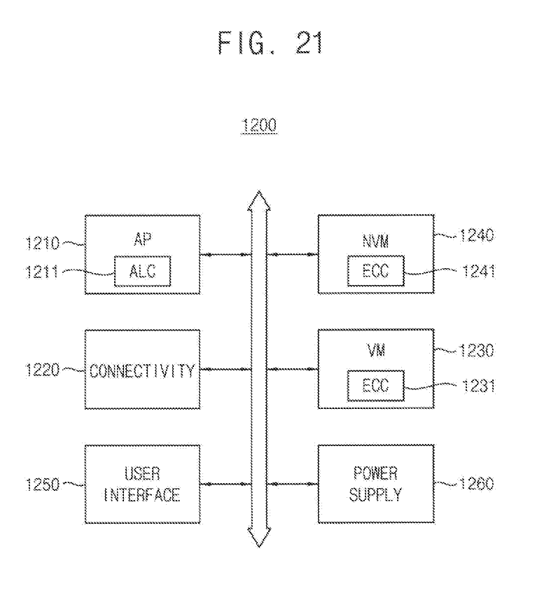

FIG. 20B illustrates a high bandwidth memory (HBM) organization. Referring to FIG. 20B, an HBM 1100 may be configured to have a stack of multiple DRAM semiconductor dies 1120, 1130, 1140, and 1150. The HBM of the stack structure may be optimized by a plurality of independent interfaces called channels. Each DRAM stack may support up to 8 channels in accordance with the HBM standards. FIG. 21B shows an example stack containing 4 DRAM semiconductor dies 1120, 1130, 1140, and 1150, and each DRAM semiconductor die supports two channels CHANNEL0 and CHANNEL1.

Each channel provides access to an independent set of DRAM banks. Requests from one channel may not access data attached to a different channel. Channels are independently clocked, and need not be synchronous. The HBM 1100 may further include an interface die 1110 or a logic die disposed at the bottom of the stack structure to provide signal routing and other functions. Some functions for the DRAM semiconductor dies 1120, 1130, 1140, and 1150 may be implemented in the interface die 1110.

At least one of the DRAM semiconductor dies 1120, 1130, 1140, and 1150 may include an ECC circuit configured to on-die ECC according to an exemplary embodiment of the inventive concept.

FIG. 21 is a block diagram illustrating a mobile system according to an exemplary embodiment of the inventive concept.

Referring to FIG. 21, a mobile system 1200 includes an application processor 1210, a connectivity circuit 1220, a volatile memory device (VM) 1230, a nonvolatile memory device (NVM) 1240, a user interface 1250, and a power supply 1260.

The application processor 1210 may execute computer instructions stored in computer-readable media (e.g., memory devices), including applications such as a web browser, a game application, a video player, etc. The connectivity circuit 1220 may perform wired or wireless communication with an external device. The volatile memory device 1230 may store data processed by the application processor 1210, or may operate as a working memory. For example, the volatile memory device 1230 may be a dynamic random access memory, such as double data rate synchronous dynamic random-access memory (DDR SDRAM), low power double data rate synchronous dynamic random-access memory (LPDDR SDRAM), graphics double data rate synchronous dynamic random-access memory (GDDR SDRAM), Rambus dynamic random-access memory (RDRAM), etc. The nonvolatile memory device 1240 may store a boot image for booting the mobile system 1200. The user interface 1250 may include at least one input device, such as a keypad, a touch screen, etc., and at least one output device, such as a speaker, a display device, etc. The power supply 1260 may supply a power supply voltage to the mobile system 1200. In exemplary embodiments of the inventive concept, the mobile system 1200 may further include a camera image processor (CIS), and/or a storage device, such as a memory card, a solid state drive (SSD), a hard disk drive (HDD), a CD-ROM, etc.

The volatile memory device 1230 and/or the nonvolatile memory device 1240 may include ECC circuits 1231 and 1241 to perform on-die ECC according to exemplary embodiments of the inventive concept, as described with reference to FIGS. 1 through 19. The application processor 1210 may include an ECC allocator ALC 1211 to determine an on-die ECC level corresponding to the write data based on the importance degree of the write data.

The inventive concept may be applied to memory devices and systems including memory devices. For example, the inventive concept may be applied to systems such as a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, etc.

The semiconductor memory device, the memory system, and the method of controlling an on-die ECC according to exemplary embodiments of the inventive concept may reduce a size of the semiconductor memory device and enhance efficiency of the on-die ECC by applying different on-die ECC levels depending on an importance degree of write data.

While the inventive concept has been shown and described with reference to exemplary embodiments thereof, it will be apparent to those of ordinary skill in the art that various modifications in form and details may be made thereto without materially departing from the spirit and scope of the inventive concept as set forth by the following claims.

What is claimed is:

1. A semiconductor memory device comprising:
a memory cell array; and
an error check and correction (ECC) circuit configured to perform ECC encoding of write data that are stored in the memory cell array and perform ECC decoding of read data corresponding to the write data that are read out from the memory cell array, based on an on-die ECC level corresponding to the write data,
wherein the on-die ECC level is determined among a plurality of on-die ECC levels depending on an importance degree of the write data.

2. The semiconductor memory device of claim 1, wherein the on-die ECC level corresponding to the write data is higher as the importance degree of the write data increases, and a ratio of a bit number of parity data corresponding to the write data to a bit number of the write data is higher as the on-die ECC level corresponding to the write data increases.

3. The semiconductor memory device of claim 1, wherein a plurality of memory regions included in the memory cell array have fixed configurations such that a ratio of a size of a data region and a size of a parity region is different with respect to at least two memory regions among the plurality of memory regions,
the write data is stored in the data region, and
parity data corresponding to the write data is stored in the parity region.

4. The semiconductor memory device of claim 1, wherein a plurality of memory regions included in the memory cell array have variable configurations such that a ratio of a size of a data region and a size of a parity region is different with respect to at least two memory regions among the plurality of memory regions and is variable,
the write data is stored in the data region, and
parity data corresponding to the write data is stored in the parity region.

5. The semiconductor memory device of claim 1, wherein the memory cell array includes a plurality of bank arrays,
each of the plurality of bank arrays includes a data region in which the write data are stored and a parity region in which parity data corresponding to the write data are stored, and
each of the plurality of bank arrays corresponds to one of the plurality of on-die ECC levels.

6. The semiconductor memory device of claim 5, wherein a ratio of a size of the data region and a size of the parity region is different with respect to at least two bank arrays among the plurality of bank arrays.

7. The semiconductor memory device of claim 6, wherein,
an entire row size of each of the at least two bank arrays is substantially identical,
an entire column size of each of the at least two bank arrays is substantially identical,
a row size of the data region of each of the at least two bank arrays is substantially identical,
a row size of the parity region of each of the at least two bank arrays is substantially identical, and
a ratio of a column size of the data region and a column size of the parity region of each of the at least two bank arrays is different.

8. The semiconductor memory device of claim 6, wherein,
an entire row size of each of the at least two bank arrays is substantially identical,
an entire column size of each of the at least two bank arrays is different,
a row size of the data region of each of the at least two bank arrays is substantially identical,
a row size of the parity region of each of the at least two bank arrays is substantially identical, and
a ratio of a column size of the data region and a column size of the parity region of each of the at least two bank arrays is different.

9. The semiconductor memory device of claim 6, wherein,
an entire row size of each of the at least two bank arrays is substantially identical,
an entire column size of each of the at least two bank arrays is substantially identical,
a column size of the data region of each of the at least two bank arrays is substantially identical,
a column size of the parity region of each of the at least two bank arrays is substantially identical, and
a ratio of a row size of the data region and a row size of the parity region of each of the at least two bank arrays is different.

10. The semiconductor memory device of claim 6, wherein,
an entire row size of each of the at least two bank arrays is different,
an entire column size of each of the at least two bank arrays is substantially identical,
a column size of the data region of each of the at least two bank arrays is substantially identical,
a column size of the parity region of each of the at least two bank arrays is substantially identical,
a row size of the data region of each of the at least two bank arrays is substantially identical, and
a ratio of a row size of the data region and a row size of the parity region of each of the at least two bank arrays is different.

11. The semiconductor memory device of claim 5, wherein at least one bank array among the plurality of bank arrays further includes a hybrid region configured to store the write data or the parity data selectively depending on the on-die ECC level assigned to the at least one bank array.

12. The semiconductor memory device of claim 11, wherein input-output nodes of the hybrid region are selectively connected to a portion of parity nodes of the ECC circuit or a portion of data nodes of the ECC circuit.

13. The semiconductor memory device of claim 1, wherein an operating system is stored in a memory region of the memory cell array having a highest on-die ECC level among the plurality of on-die ECC levels.

14. The semiconductor memory device of claim 1, wherein the memory cell array includes a plurality bank arrays, and
the on-die ECC level corresponding to the write data is determined among the plurality of on-die ECC levels based on a plurality of bank addresses respectively representing the plurality of the bank arrays.

15. A memory system comprising:
at least one semiconductor memory device; and
a memory controller configured to control the at least one semiconductor memory device,
wherein the memory controller determines an on-die ECC level corresponding to write data among a plurality of on-die ECC levels depending on an importance degree of the write data that are stored in a memory cell array of the at least one semiconductor memory device, and
wherein the at least one semiconductor memory device performs ECC encoding of the write data and ECC decoding of read data corresponding to the write data based on the on-die ECC level corresponding to the write data.

16. The memory system of claim 15, wherein a plurality of memory regions included in the memory cell array have fixed configurations such that a ratio of a size of a data region and a size of a parity region is different with respect to at least two memory regions among the plurality of memory regions,
wherein the write data is stored in the data region,
wherein parity data corresponding to the write data is stored in the parity region,
wherein the at least one semiconductor memory device provides information on the fixed configurations to the memory controller, and
wherein the memory controller determines a write address of the write data using the information on the fixed configurations.

17. The memory system of claim 15, wherein a plurality of memory regions included in the memory cell array have variable configurations such that a ratio of a size of a data region and a size of a parity region is different with respect to at least two memory regions among the plurality of memory regions and is variable,
wherein the write data is stored in the data region,
wherein parity data corresponding to the write data is stored in the parity region,
wherein the memory device sets the variable configurations using information on the variable configurations provided from the memory controller, and
wherein the memory controller determines a write address of the write data based on the information on the variable configurations.

18. A method of controlling an error check and correction (ECC) of a semiconductor memory device, the method comprising:
determining, by a memory controller, an on-die ECC level corresponding to write data among a plurality of on-die ECC levels depending on an importance degree of the write data that are stored in a memory cell array of the semiconductor memory device; and
performing, by the semiconductor memory device, ECC encoding of the write data and ECC decoding of read data corresponding to the write data based on the on-die ECC level corresponding to the write data.

19. The method of claim 18, further comprising:
forming a plurality of memory regions in the memory cell array, wherein the plurality of memory regions have configurations respectively corresponding to the plurality of on-die ECC levels; and
providing, from the semiconductor memory device to the memory controller, information on the configurations of the plurality of memory regions.

20. The method of claim 18, further comprising:
providing, from the semiconductor memory device to the memory controller, information on configurations of a plurality of memory regions included in the memory cell array; and
setting a data region and a parity region in each of the plurality of memory regions, wherein the write data is stored in the data region and parity data corresponding to the write data is stored in the parity region.
